(19) United States
(12) Patent Application Publication
(10) Pub. No.: US 2014/0247576 A1
(43) Pub. Date: Sep. 4, 2014

(54) HIGH-VOLTAGE PLATFORM

(71) Applicants: German Kuhn, Erlangen (DE); Achim Von Seck, Wachenroth Ot Weingartsgreuth (DE)

(72) Inventors: German Kuhn, Erlangen (DE); Achim Von Seck, Wachenroth Ot Weingartsgreuth (DE)

(73) Assignee: SIEMENS AKTIENGESELLSCHAFT, Muenchen (DE)

(21) Appl. No.: 14/355,332

(22) PCT Filed: Oct. 31, 2011
(86) PCT No.: PCT/EP2011/069131

§ 371 Date: Apr. 30, 2014

(51) Int. Cl. H05K 7/00

(52) U.S. Cl. CPC H05K 7/00
USPC 361/813

(57) ABSTRACT

A device for carrying high-voltage equipment in an electrically-insulated manner includes a carrier platform which is mounted and electrically insulated by way of support insulators. The high-voltage equipment is supported on the carrier platform. The carrier platform has primary carriers with which the platform rests on the support insulators. In order to achieve a device that prevents deflections of the carrier platform in a cost-effective manner, the high-voltage equipment is at least partially arranged in a carrier structure that is equipped with support feet, with each foot arranged vertically above a primary carrier.

The invention relates to a device for carrying high-voltage components in an electrically insulated manner, having a carrying platform which is elevated and electrically insulated by means of supporting insulators and on which the high-voltage equipment is arranged, wherein the carrying platform has primary carriers by way of which the carrying platform rests on the supporting insulators.

A device of this kind is known, for example, from the field of energy transmission. Platforms which serve to carry high-voltage equipment in an insulated manner are used in so-called Flexible AC Transmission Systems (FACTS) and, in particular, in a device for fixed series compensation platforms. A platform of this kind has, for example, an area of 40 m² and is arranged 5 m above the ground. Electrically insulating supporting insulators are used for providing the elevation. The high-power equipment is designed for voltages of up to 500 kV. Heavy capacitor banks, which can weigh up to 30 tonnes, are used in the case of series compensation (Fixed Series Compensation, FSC) in particular. Said capacitor banks are generally situated in the center of the platform and generate a high degree of bending in the secondary structure of the platform. On account of this bending, considerable stresses are generated in the statically indeterminate structure of the capacitor banks.

In order to prevent the platform from sagging as far as possible, relatively thick primary carriers and secondary carriers have been used to date. Therefore, in devices according to the prior art, a large number of primary carriers are provided in order to keep the bending of the secondary carrier layer within the required limit values. Furthermore, additional supporting insulators have been used beneath the center of the carrying platform.

The object of the invention is to provide a device of the kind cited in the introductory part with which sagging of the carrying platform is prevented in a cost-effective manner.

The invention solves this problem by at least some of the high-voltage equipment being arranged in a carrying structure which is equipped with feet, wherein each foot is arranged perpendicularly above a primary carrier.

According to the invention, it is possible to introduce the weight of the heaviest item of high-voltage equipment, in particular of the capacitors, directly into the primary carriers and therefore into the supporting insulators. Sagging of the secondary carrier layer is prevented in a cost-effective manner according to the invention. Therefore, the number of transverse beams, but also of supporting insulators, can be reduced according to the invention.

The carrying structure expediently has at least one truss with carrying frames which are arranged one above the other in the form of a stack. A carrying structure of this kind allows the capacitors to be stacked one above the other, as a result of which the number of feet and therefore the number of primary carriers required is further reduced. According to a further development which is expedient in this respect, each carrying frame has two carrying levels.

At least some of the feet are expediently equipped to form supporting insulators. The supporting insulators increase the quality of the insulation to a considerable extent.

The carrying frames which are stacked one above the other are advantageously supported against one another by means of spacing insulators. This likewise increases the insulation of the entire device.

According to a preferred refinement of the invention, the trusses are connected to one another in a flexurally rigid manner by means of horizontal insulators. With the aid of the flexurally rigid connection, it is possible to use two trusses, wherein each truss is equipped only with two feet. In this case, the feet of each truss are arranged on a straight line, wherein the straight lines of the two trusses run parallel to one another. In this way, the four feet of two trusses can be arranged directly above two primary carriers of the carrying platform.

The capacitors in the trusses are expediently connected to one another by steel bands. This provides further bracing of the weight of the capacitor banks.

Further expedient refinements and advantages of the invention are the subject matter of the following description of exemplary embodiments of the invention with reference to the figures in the drawing in which identical reference numerals refer to components which act in the same way, and in which

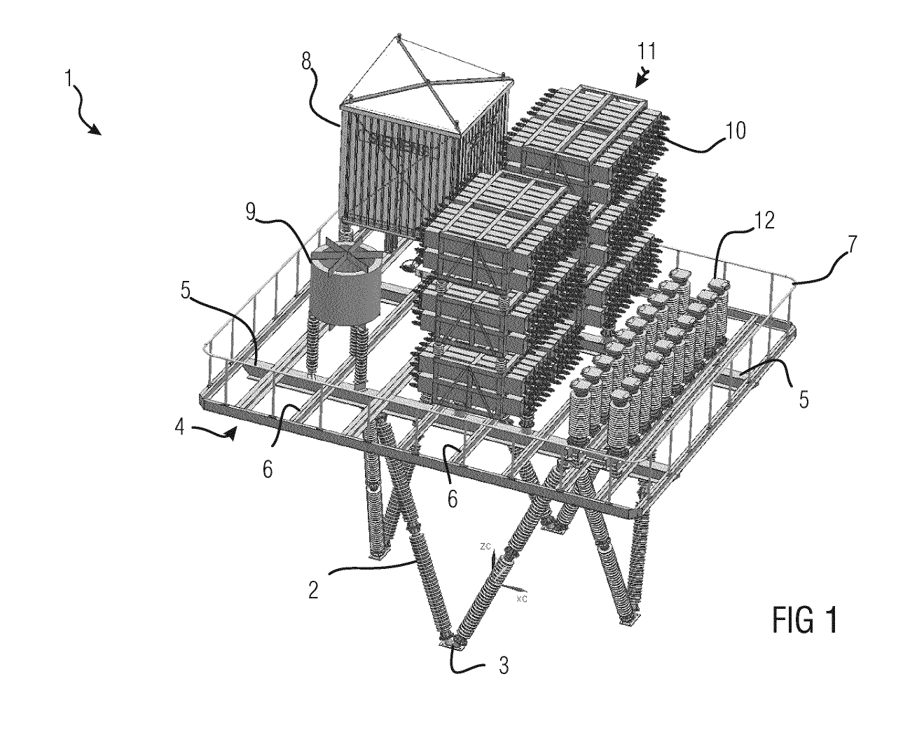

FIG. 1 shows a perspective view of an exemplary embodiment of the device according to the invention, and

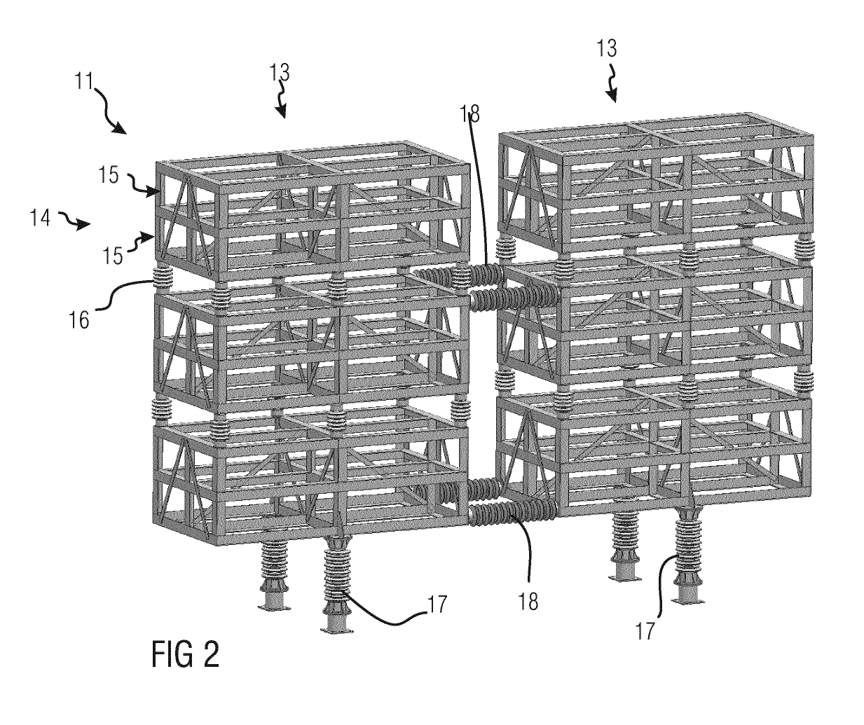

FIG. 2 likewise shows a perspective view of a carrying structure.

FIG. 1 is a perspective illustration of an exemplary embodiment of the device 1 according to the invention. In the exemplary embodiment shown, the device 1 has supporting insulators 2 which extend from a concrete foundation 3, which is recessed in the ground, up to a carrying platform 4 in a sloping manner. The carrying platform 4 is supported on the supporting insulators 2 in this way. In the process, the supporting insulators 2 provide electrical insulation between the ground potential and a possible high-voltage potential which is applied to the carrying platform 4. The carrying platform 4 comprises so-called primary carriers 5 by way of which the carrying platform 4 is supported directly on the supporting insulators 2. So-called secondary carriers 6 rest on the primary carriers and extend at right angles to the primary carriers 5. Grids with cutouts are arranged on the primary carriers, but said grids are not illustrated in the representation of the exemplary embodiment shown in FIG. 1. In this case, a railing 7 is shown in said figure, said railing surrounding the carrying platform 4 at its outer contour so as to close it.

High-voltage equipment in the form of a spark gap 8, a coil 9, capacitors 10 and also further high-voltage components 11 are arranged on the carrying platform 4. The capacitors have the highest inherent weight. They can weigh up to 30 tonnes and are therefore arranged in the center of the carrying platform. In order to largely prevent deformation of the platform due to the heavy capacitors 10, the capacitors 10 are arranged in a carrying structure 11 which is illustrated in greater detail in FIG. 2.

In the exemplary embodiment shown, the carrying structure 11 has two trusses 13 which have carrying frames 14, which are each stacked one on the other, and are mounted such that they are insulated from one another by spacing insulators 16. Said spacing insulation is necessary since different potentials can be applied to the capacitors 10 in the carrying structure 11.

Each carrying frame 14 forms two carrying levels 15 in which the capacitors 10 are arranged. In order to increase the rigidity of the supporting structure 11, the capacitors 10 are lashed firmly to one another in the carrying levels 15 by spacing bands. Two feet 17 can be seen beneath each truss 13. Furthermore, the two trusses 13 are firmly connected to one another by flexurally rigid spacing insulators 18. The feet 17 of each truss are arranged on a straight line, wherein the straight lines of the two trusses 13 run parallel to one another. In this way, the carrying structure 11 can be mounted on two primary carriers 5 which are oriented parallel to one another, as shown in FIG. 1, wherein each foot 17 is arranged perpendicularly directly above the primary carrier 5. The weight of all of the capacitors 10 is introduced directly into the primary carriers 5 and therefore into the supporting insulators 2. Deformation of the secondary carriers 6 can be prevented in this way. Owing to the flexurally rigid connection of two trusses 13, the feet 17 of one truss are at such a distance from the feet 17 of the other truss 13 that only two primary carriers 5 have to be used for the carrier platform 4. Additional supporting insulators 2 for preventing sagging are likewise rendered superfluous.

Therefore, the invention provides a device 1 which is cost-effective and in which it was possible to largely prevent sagging of the secondary carriers 6 at the same time.

1-8. (canceled)

9. A device for carrying high-voltage equipment in an electrically insulated manner, the device comprising:
a carrier platform having the high-voltage equipment disposed thereon;
supporting insulators elevating and electrically insulating said carrier platform;
said carrier platform having primary carriers by way of which said carrier platform rests on said supporting insulators;
the high-voltage equipment being at least partly mounted in a carrying structure equipped with feet, with each of said feet being arranged perpendicularly above a respective said primary carrier.

10. The device according to claim 9, wherein said carrying structure has at least one truss with carrying frames disposed above one another to form of a stack.

11. The device according to claim 10, wherein each of said carrying frames has two carrying levels.

12. The device according to claim 9, wherein at least some of said feet are supporting insulators.

13. The device according to claim 11, which comprises spacing insulators supporting said carrying frames against one another.

14. The device according to claim 10, wherein said at least one truss is one of a plurality of trusses and which comprises horizontal insulators disposed to connect said trusses to one another in a flexurally rigid manner.

15. The device according to claim 9, which comprises high-powered capacitors disposed in said carrying structure.

16. The device according to claim 9, wherein said carrying structure is disposed centrally on said carrier platform.
